(19) United States
(12) Patent Application Publication
(10) Pub. No.: US 2005/0249353 A1
(43) Pub. Date: Nov. 10, 2005

(54) System and method for detecting fault conditions on audio output channels

(75) Inventors: Dennis P. Ward, Ypsilanti, MI (US); Richard D. Zerod, Chelsea, MI (US)

Correspondence Address: VISTEON, C/O BRINKS HOFER GILSON & LIONE, PO BOX 10395, CHICAGO, IL, 60610, US

(73) Assignee: Visteon Global Technologies, Inc.

(21) Appl. No.: 10/840,023

(22) Filed: May 5, 2004

(51) Int. Cl. H04R 29/00; H03G 11/00

(52) U.S. Cl. 381/58; 381/55

(57) ABSTRACT

A system for detecting fault conditions in an audio system is provided. The audio system includes a remote audio generation device connected to an amplifier unit through a wire harness. A remote audio generation device being, for example, a CD unit or DVD player located in the trunk of the vehicle. The system would detect fault conditions that might occur in the wire harness and optionally transmit a diagnostic signal to an audio system controller. The remote audio generation device includes an audio generation circuit, a switch, and a fault detection circuit. The audio generation circuit creates an audio signal from a transmission or stored media. Selectively coupling the audio generation circuit with a wire harness, the switch will isolate the audio generation circuit if a fault condition occurs. To detect the fault condition, a fault detection circuit monitors the audio output and provides a control signal causing the switch to decouple the audio generation circuit during a fault condition.

### BACKGROUND

1. Field of the Invention

The present invention generally relates to a method and system for detecting fault conditions in an audio system.

2. Description of Related Art

To conserve space in automotive applications, audio generation devices such as CD, or satellite radio, have been packaged separately from the radio amplifier and placed in remote locations, such as, the trunk of a vehicle. The remote audio generation devices are connected back to the radio amplifier through a wire harness that runs through the body of the vehicle. Over time, the wire harness can become damaged causing a short from the audio output of the remote audio generation device to either an electrical ground or a power source, such as, the battery. A fault condition, such as, a direct connection to the battery or electrical ground can cause significant damage to both the remote audio generation device and the radio amplifier. Many radio amplifier systems today have built-in clip detection to protect the speakers from the radio amplifier output or the internal circuitry of the radio amplifier from external devices. However, these systems do not provide protection to the remote audio generation device and further provide no ability for the service technician to diagnose where the fault condition occurred.

In view of the above, it is apparent that there exists a need for an improved system for detecting fault conditions in an audio system.

### SUMMARY

In satisfying the above need, as well as overcoming the enumerated drawbacks and other limitations of the related art, the present invention provides a system for detecting fault conditions in an audio system. The audio system includes a remote audio generation device connected to an amplifier unit through a wire harness. A remote audio generation device being, for example, a CD unit or DVD player located in the trunk of the vehicle. The system would detect fault conditions that might occur in the wire harness and optionally transmit a diagnostic signal to an audio system controller. The remote audio generation device includes an audio generation circuit, a switch, and a fault detection circuit. The audio generation circuit creates an audio signal from a transmission or stored media. Selectively coupling the audio generation circuit with a wire harness, the switch will isolate the audio generation circuit if a fault condition occurs. To detect the fault condition, a fault detection circuit monitors the audio output and provides a control signal causing the switch to decouple the audio generation circuit during a fault condition.

In another aspect of the present invention, the fault detection circuit samples the audio output to determine if its voltage is above an upper limit or below a lower limit. If the audio output is outside the upper or lower limit, a counter is incremented, such that a control signal is generated if the audio output exceeds the threshold for a predetermined number of samples. Alternatively, the multiple samples may be averaged and the average compared to the upper and lower limit. In addition, the fault detection circuit is configured to delay for a predetermined time period before sampling once a fault condition has occurred.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a schematic view of a system for detecting fault conditions in an audio system in accordance with the present invention; and

FIG. 2 is a flow chart illustrating a method for detecting fault conditions in an audio system in accordance with the present invention.

### DETAILED DESCRIPTION

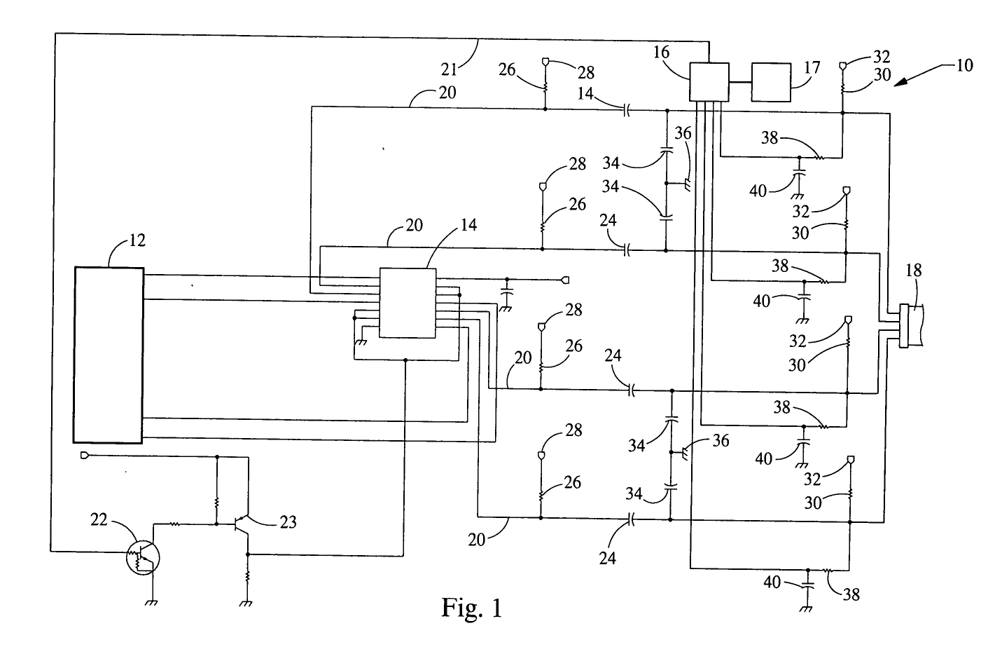

Referring now to FIG. 1, a system embodying the principles of the present invention is illustrated therein and designated at 10. As its primary components, the system 10 includes an audio generation circuit 12, a switch 14, and a fault detection circuit 16.

The audio generation circuit 12 may receive a transmission or read from stored media to provide an audio output signal. Often, the audio output signal is provided from the audio generation circuit 12 as two differential channels as shown in FIG. 1. The audio output signal is provided to a switch 14, such as analog switch CD4066, manufactured by Fairchild Semiconductors. The switch 14 connects the audio output signals to a wire harness 18 along audio output lines 20. The wire harness 18 runs between the remote audio generation device and a radio amplifier (not shown). The switch 14 is configured to selectively connect the audio generation circuit 12 with the wire harness 18. However, if a fault condition occurs, the switch 14 will disconnect the audio generation circuit 12 from the audio output lines 20.

To detect a fault condition, the fault detection circuit 16 monitors the audio signal from the audio output lines 20. If the fault detection circuit 16 determines a fault condition exists, a diagnostic signal is provided to an audio system controller 17 where the diagnostic signal is stored in memory. In addition, a control signal is provided along line 21 to a switching transistor 22. Transistor 22 and transistor 23 cooperatively act to simultaneously activate or de-activate all of the audio output lines 20.

To provide DC filtering, each audio output line 20 is in electrical series connection with a first capacitor 24, connected between the switch 14 and the wire harness 18. A first resistor 26 is connected between the analog switch 14 and a voltage source 28. Similarly, a second resistor 30 is connected in electrical series connection between the wire harness 18 and the power source 32. The fault detection circuit 16 is in communication with each audio output line 20 of the switch 14 through the first capacitor 24.

To protect the input of the fault detection circuit 16, a resistor 38 and capacitor 40 are provided in communication with the wire harness 18. The input of the fault detection circuit 16 is in connection with the first capacitor 24 through resistor 38. Further, the capacitor 40 is connected between the resistor 38 and an electrical ground.

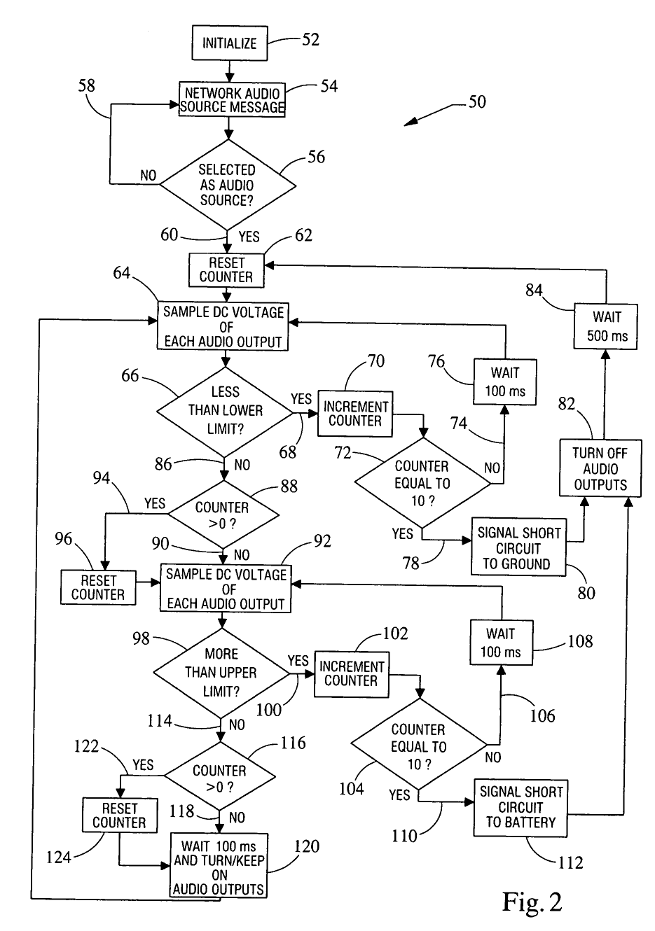

Now referring to FIG. 2, a method 50 is provided for detecting fault conditions and may be implemented in the fault detection circuit 16. The method 50 begins in block 52 where algorithm variables are initialized. The system 10 checks for an audio network message indicating the remote audio generation device has been selected, as denoted by block 54. If the remote audio generation device has not been selected, the method flows along line 58 to block 54, where the remote audio generation device continues to monitor the audio network. If the remote audio generation device is selected as the audio source, the method flows along line 60 and the fault counter is reset as denoted by block 62. The fault detection system 16 samples the voltage of each audio output 20 as denoted by block 64. In block 66, the fault detection circuit 16 determines if the voltage on the audio output lines 20 are less than a lower limit. If the voltage of the audio output signals 20 is less than the lower limit, the method flows along line 68 and the fault counter is incremented as denoted by block 70. In block 72, the fault detection circuit 16 determines if the fault counter is equal to 10. If the fault counter is not equal to 10, then the method flows along line 74 where the fault detection device delays sampling for a predetermined time period, such as 100 milliseconds, as denoted by block 76. After the delay, the system again samples the voltage output of the audio outputs 20 as denoted by block 64.

Referring again to block 72, if the fault counter is equal to 10, the method flows along line 78 and a signal is generated indicating a short circuit to ground condition has occurred as denoted by block 80. In block 82, the fault detection circuit 16 provides a signal to the switch 14 to deactivate the audio outputs 20. In block 84, the system delays for a second predetermined time period, such as 500 milliseconds, before resetting the counter as denoted by block 62 and continuing to sample the audio outputs 20 as provided by block 64.

Referring again to block 66, if the voltage of the audio output 20 is not less than the lower limit, the method flows along line 86 and the fault detection circuit 16 determines if the fault counter is greater than zero as denoted by block 88. If the fault counter is not greater than zero, the method flows along line 90 where the voltage of the audio output line is sampled as denoted by block 92.

Referring again to block 88, if the fault counter is greater than zero, the method flows along line 94 and the fault counter is reset as denoted by block 96. The fault detection circuit 16 then samples the voltage of the audio output 20 as denoted by block 92. In block 98, the fault detection circuit determines if the voltage of the audio output 20 is greater than an upper limit. Alternatively, the fault detection system 16 may sample the voltage multiple times and compare the upper and lower limits to the average voltage of the multiple samples. If the voltage on the audio output 20 is greater than the upper limit, the method flows along line 100 and the fault counter is incremented as denoted by block 102. In block 104, the fault detection circuit determines if the fault counter is equal to a predetermined count, such as 10. If the fault counter is not equal to the predetermined count, the method flows along line 106 and the system delays for a predetermined time period as denoted by block 108. After the delay, the fault detection circuit 16 again samples the audio output 20 as denoted by block 92.

Referring again to block 104, if the fault counter is equal to the predetermined count, the method flows along line 110 and a diagnostic signal indicating a short circuit to battery condition is generated as denoted by block 112. In addition, the fault detection circuit 116 generates a control signal that is provided to switch 14 to disable the audio outputs 20 as denoted by block 82. The system delays for a predetermined time period as denoted by block 84 prior to resetting the fault counters in block 62 and again sampling the voltage on the audio output 20 as denoted by block 64.

Referring again to block 98, if the voltage of the audio output 20 is not more than the upper limit, the method flows along line 114 and the fault detection circuit 16 determines if the fault counter is greater than zero as denoted by block 116. If the fault counter is greater than zero, the method flows along line 122 and the fault counter is reset as denoted by block 124. As denoted in block 120, the system delays for a predetermined time period and activates the audio outputs 20 if the audio outputs are currently deactivated. Alternatively, if block 116 determines the counter is not greater than zero, the method flows along line 118 to block 120 where the system delays for a predetermined time period and turns on the audio outputs 20 if they are currently de-activated. The method then flows back to block 64 where the voltage of the audio output is sampled again repeating the cycle.

As a person skilled in the art will readily appreciate, the above description is meant as an illustration of implementation of the principles this invention. This description is not intended to limit the scope or application of this invention in that the invention is susceptible to modification, variation and change, without departing from spirit of this invention, as defined in the following claims.

1. A system for detecting fault conditions in an audio system, the audio system including a remote audio generation device, an amplifier unit, and a wire harness connected therebetween, the system comprising:
an audio generation circuit;
a switch coupled to the audio generation circuit configured to selectively connect the audio generation circuit to the amplifier unit through the wire harness; and
a fault detection circuit configured to monitor an audio output of the switch to detect fault conditions and provide a control signal to a control input of the switch to selectively disconnect the audio generation circuit from the wire harness.

2. The system according to claim 1, wherein the fault detection circuit is configured to send a diagnostic signal to an audio system controller when a fault condition occurs.

3. The system according to claim 2, wherein the audio system controller stores the diagnostic signal in memory.

4. The system according to claim 1, wherein the fault detection circuit is configured to generate the control signal if the audio output is above a threshold value.

5. The system according to claim 4, wherein the fault detection circuit includes a counter, and the fault detection circuit is configured to generate the control signal if the audio output exceeds the threshold for a predetermined number of samples.

6. The system according to claim 1, wherein the fault detection circuit is configured to generate the control signal if the audio output is below a threshold value.

7. The system according to claim 6, wherein the fault detection circuit includes a counter, and the fault detection circuit is configured to generate the control signal if the audio output exceeds the threshold for a predetermined number of samples.

8. The system according to claim 1, wherein the fault detection circuit is configured to average multiple samples to generate an average output and compare the average output to a threshold.

9. The system according to claim 1, wherein the fault detection circuit is configured to delay for a predetermined time period before sampling once a fault condition has occurred.

10. The system according to claim 1, further comprising:
a transistor coupled to the switch, the transistor being configured to simultaneously control multiple outputs of the switch simultaneously.

11. The system according to claim 1, further comprising:
a first capacitor in electrical series connection between the switch and the wire harness.

12. The system according to claim 11, further comprising:
a first resistor between the switch and a power source.

13. The system according to claim 12, further comprising:
a second resistor between the wire harness and the power source.

14. The system according to claim 13, further comprising:
a second capacitor between the wire harness and an electrical ground.

15. The system according to claim 1, wherein the fault detection circuit is coupled to the audio outputs of the switch through the first capacitor.

16. A method for detecting fault conditions in an audio system, the audio system including a remote audio generation device, an amplifier unit, and a wire harness connected therebetween, the method comprising:
generating an audio signal using an audio generation circuit;
selectively connecting the audio generation circuit to the amplifier unit through the wire harness using a switch; and
monitoring an audio output of the switch to detect fault conditions; and
providing a control signal to a control input of the switch to selectively disconnect the audio generation circuit from the wire harness.

17. The method according to claim 16, further comprising providing a diagnostic signal to an audio system controller when a fault condition occurs.

18. The method according to claim 17, further comprising storing the diagnostic signal in memory.

19. The method according to claim 16, wherein the fault detection circuit is configured to generate the control signal if the audio output is above a threshold value.

20. The method according to claim 19, wherein the fault detection circuit includes a counter, and the fault detection circuit is configured to generate the control signal if the audio output exceeds the threshold for a predetermined number of samples.

21. The method according to claim 16 wherein the fault detection circuit is configured to generate the control signal if the audio output is below a threshold value.

22. The method according to claim 21, wherein the fault detection circuit includes a counter, and the fault detection circuit is configured to generate the control signal if the audio output exceeds the threshold for a predetermined number of samples.

23. The method according to claim 16, wherein monitoring the audio output includes averaging multiple samples to generate an average output and comparing the average output to a threshold.

24. The method according to claim 16, further comprising delaying for a predetermined time period before sampling once a fault condition has occurred.
